(19) United States
(12) Patent Application Publication
(10) Pub. No.: US 2013/0146468 A1
(43) Pub. Date: Jun. 13, 2013

(54) CHEMICAL VAPOR DEPOSITION (CVD) OF RUTHENIUM FILMS AND APPLICATIONS FOR SAME

(71) Applicants: HOON KIM, Santa Clara, CA (US); SANG HYEOB LEE, Fremont, CA (US); WEI TI LEE, San Jose, CA (US); SESHADRI GANGULI, Sunnyvale, CA (US); HYOUNG-CHAN HA, San Jose, CA (US); SANG HO YU, Cupertino, CA (US)

(72) Inventors: HOON KIM, Santa Clara, CA (US); SANG HYEOB LEE, Fremont, CA (US); WEI TI LEE, San Jose, CA (US); SESHADRI GANGULI, Sunnyvale, CA (US); HYOUNG-CHAN HA, San Jose, CA (US); SANG HO YU, Cupertino, CA (US)

(73) Assignee: APPLIED MATERIALS, INC., Santa Clara, CA (US)

(21) Appl. No.: 13/314,926

(22) Filed: Dec. 8, 2011

(51) Int. Cl. C23C 28/02; C23C 16/56; B05D 5/12; C23C 16/44

(52) U.S. Cl. 205/186; 427/248.1; 427/255.7; 427/123

(57) ABSTRACT

Methods for depositing ruthenium-containing films are disclosed herein. In some embodiments, a method of depositing a ruthenium-containing film on a substrate may include depositing a ruthenium-containing film on a substrate using a ruthenium-containing precursor, the deposited ruthenium-containing film having carbon incorporated therein; and exposing the deposited ruthenium-containing layer to a hydrogen-containing gas to remove at least some of the carbon from the deposited ruthenium-containing film. In some embodiments, the hydrogen-containing gas exposed ruthenium-containing film may be subsequently exposed to an oxygen-containing gas to at least one of remove at least some carbon from or add oxygen to the ruthenium-containing film. In some embodiments, the deposition and exposure to the hydrogen-containing gas and optionally, the oxygen-containing gas may be repeated to deposit the ruthenium-containing film to a desired thickness.

### FIELD

Embodiments of the present invention generally relate to methods of processing substrates, and more specifically, to methods for depositing ruthenium-containing films.

### BACKGROUND

As device nodes get smaller (for example, approaching dimensions of about 22 nm or less), manufacturing challenges become more apparent. For example, the combined thickness of barrier and seed layers of typical materials deposited in an opening prior to filling the opening, for example via electroplating, to form an interconnect structure may result in reduced efficiency of the electroplating process, reduced process throughput and/or yield, or the like.

Ruthenium, deposited for example by chemical vapor deposition (CVD), has become a promising candidate as a seed layer for a copper interconnect. However, ruthenium by itself cannot be a copper barrier and barrier layers such as TaN/Ta are still needed prior to ruthenium deposition.

Unfortunately, the deposition of ruthenium is challenging. For example, the deposition may include such limitations as low deposition rate, poor step coverage, high resistivity, and poor adhesion to barrier layers. Although some ruthenium deposition techniques have been reported that satisfy some of these requirements, no satisfactory process has yet been developed that satisfies all of the requirements. For example, chemical vapor deposition (CVD) with some ruthenium precursors have shown good layer resistivity, but the adhesion, deposition rate, and step coverage were all poor and thus inadequate for device applications

Thus, the inventors have provided improved methods for forming ruthenium-containing layers.

### SUMMARY

Methods for depositing ruthenium-containing films are disclosed herein. In some embodiments, a method of depositing a ruthenium-containing film on a substrate may include depositing a ruthenium-containing film on a substrate using a ruthenium-containing precursor, the deposited ruthenium-containing film having carbon incorporated therein; and exposing the deposited ruthenium-containing layer to a hydrogen-containing gas to remove at least some of the carbon from the deposited ruthenium-containing film. In some embodiments, the hydrogen-containing gas exposed ruthenium-containing film may be subsequently exposed to an oxygen-containing gas to at least one of remove at least some carbon from or add oxygen to the ruthenium-containing film. In some embodiments, the deposition and exposure to the hydrogen-containing gas and optionally, the oxygen-containing gas may be repeated to deposit the ruthenium-containing film to a desired thickness.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart of a method of depositing a ruthenium-containing film in accordance with some embodiments of the present invention.

FIGS. 2A-C depict side cross-sectional views of the stages of forming an interconnect structure in a substrate in accordance with some embodiments of the present invention.

FIG. 3 depicts a cluster tool suitable to perform methods for processing a substrate in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods for depositing ruthenium-containing films are disclosed herein. The inventive methods may advantageously allow for a ruthenium-containing film to be deposited having one or more of improved resistivity, adhesion, deposition rate, or step coverage, as compared to conventional deposited ruthenium-containing films. In some embodiments, a ruthenium-containing film may be deposited having one or more of resistivity, adhesion, deposition rate, or step coverage that is suitable for device applications. Exemplary device applications may include interconnect structures, such as vias, trenches, or the like having one or more ruthenium-containing films formed by the inventive methods disclosed herein. In some embodiments, the ruthenium-containing film may be part of a larger device, such as but not limited to, dynamic random access memory (DRAM), capacitor electrodes, or the like.

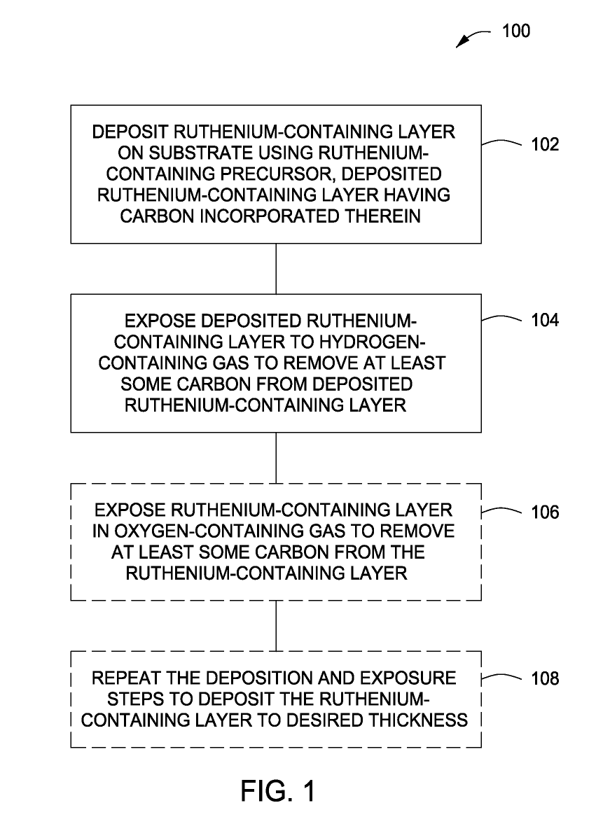

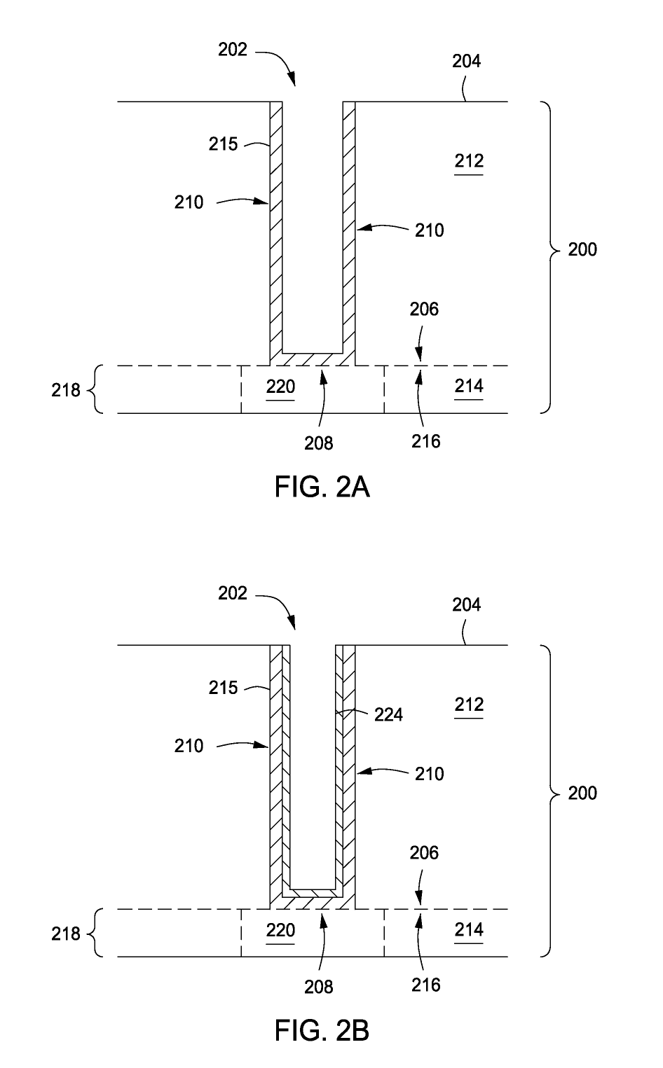

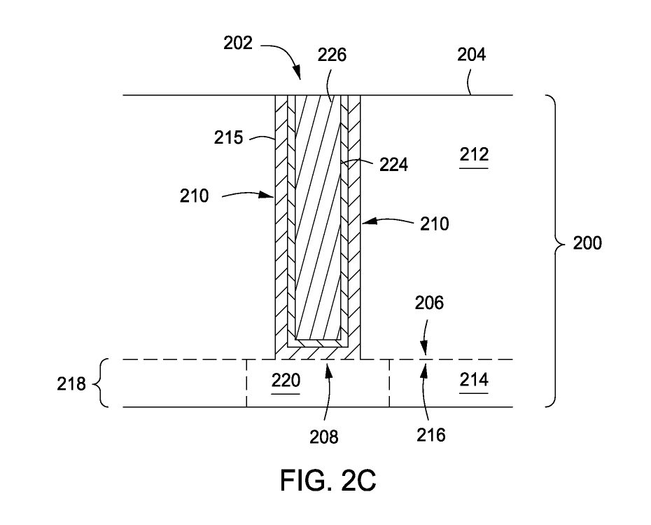

FIG. 1 depicts a flow chart for a method 100 for depositing a ruthenium-containing film in accordance with some embodiments of the present invention. The method 100 is described below with respect to the stages of fabrication of a first ruthenium-containing film as depicted in FIGS. 2A-C. The deposition of a ruthenium-containing film formed by any of the methods disclosed herein may be performed in a process chamber configured for chemical vapor deposition (CVD). The CVD chamber may be any suitable CVD chamber configured to perform the methods as disclosed herein. For example, the CVD chamber may be a standalone process chamber or a part of a cluster tool, such as one of the CENTURA®, PRODUCER®, or ENDURA® cluster tools available from Applied Materials, Inc. of Santa Clara, Calif. The method 100 may be performed completely in a single chamber, or in multiple chambers.

The method 100 may be illustratively performed on a substrate 200 having an opening 202, as depicted in FIG. 2A in accordance with some embodiments of the present invention. The opening 202 may be formed in a first surface 204 of the substrate 200 and extending into the substrate 200 towards an opposing second surface 206 of the substrate 200. The substrate 200 may be any suitable substrate having an opening formed therein. For example, the substrate 200 may comprise one or more of a dielectric material, silicon, metals, or the like. In addition, the substrate 200 may include additional layers of materials or may have one or more completed or partially completed structures formed therein or thereon. For example, the substrate 200 may include a first dielectric layer 212, such as silicon oxide, low-k, or the like, and the opening 202 may be formed in the first dielectric layer 212. In some embodiments, the first dielectric layer 212 may be disposed atop a second dielectric layer 214, such as silicon oxide, silicon nitride, silicon carbide, or the like. A conductive material (e.g., 220) may be disposed in the second dielectric layer 214 and may be aligned with the opening 202 such that the opening 202, when filled with a conductive material, provides an electrical path to/from the conductive material 220. For example, the conductive material 220 may be part of a line or via to which the interconnect is coupled.

The opening 202 may be any opening, such as a via, trench, dual damascene structure, or the like. In some embodiments, the opening 202 may have a height to width aspect ratio of at least about 5:1 (e.g., a high aspect ratio). For example, in some embodiments, the aspect ratio may be about 10:1 or greater, such as about 15:1. The opening 202 may be formed by etching the substrate using any suitable etch process. The opening 202 includes a bottom surface 208 and sidewalls 210.

In some embodiments, the sidewalls 210 may be covered with one or more layers prior to depositing metal atoms as described below. For example, the sidewalls 210 and the bottom surface 208 of the opening 202 may be covered by a barrier layer 215, such as comprising one or more of tantalum (Ta), tantalum nitride (TaN), silicon oxide (SiO₂), silicon carbon nitride, silicon oxicarbide (SiOC), or the like. The barrier layer 215 may be deposited or grown, for example in a chemical vapor deposition (CVD) chamber or in a suitable oxidation chamber. The barrier layer 215 may serve as an electrical and/or physical barrier between the substrate and one or more of the seed layer or barrier layer materials to be subsequently deposited in the opening, and/or may function as a better surface for attachment during the deposition process discussed below than a native surface of the substrate. The barrier layer 215 may have a thickness of about 5 to about 30 angstroms. In some embodiments, the barrier layer 215 may be about 15 angstroms in thickness.

In some embodiments, and as illustrated by dotted lines in FIGS. 2A-C, the opening 202 may extend completely through the substrate 200 and an upper surface 216 of a second substrate 218 may form the bottom surface 208 of the opening 202. The second substrate 218 may be disposed adjacent to the second surface 206 of the substrate 200. Further (and also illustrated by dotted lines), a conductive material (e.g., 220), for example as part of a device, such as a logic device or the like, or an electrical path to a device requiring electrical connectivity, such as a gate, a contact pad, a conductive line or via, or the like, may be disposed in the upper surface 216 of the second substrate 218 and aligned with the opening 202. In some embodiments, the conductive material 220 aligned with the opening 202 may comprise copper.

The method 100 begins at 102 where a ruthenium-containing film 224 may be deposited in the opening 202 of the first dielectric layer 212 on the substrate 200, as illustrated in FIG. 2B. In some embodiments, the ruthenium-containing film 224 contains about 70 to about 98 atomic percent ruthenium, or greater than about 80 atomic percent ruthenium).

The ruthenium-containing film 224 further has carbon (C) incorporated in the film as initially deposited. For example, the ruthenium-containing film 224 may include about 20 atomic percent carbon, or ranging from about 2 atomic percent to about 30 atomic percent carbon, or in some embodiments, from about 2 atomic percent to about 20 atomic percent. In some embodiments, the high carbon content in the initially deposited ruthenium-containing film 224 may be due to carbon-containing precursor in combination with a high deposition rate of about 60 angstroms/minute or greater, or ranging from about 10 to about 100 angstroms/minute.

The high carbon content in the initially deposited ruthenium-containing film 224 may result in a layer having an amorphous morphology. Further, the high carbon content may result in a layer having a smooth surface and/or uniform thickness. The initially deposited ruthenium-containing film 224 may have a high resistivity due to the high carbon content. In some embodiments, the resistivity in the initially deposited ruthenium-containing film 224 may range from about 100 to about 200 micro-ohm-centimeters (μΩ-cm). The initially deposited ruthenium-containing film 224 may have good step coverage, for example, in a trench, via or other high aspect ratio structure. In some embodiments, the step coverage may be about 95% or greater, or ranging from about 60 to about 99 percent. As used herein, step coverage is defined as the ratio of minimum thickness of material deposited on a sidewall of the structure to the thickness of material deposited on the field (e.g., the upper surface of the substrate).

Chemical precursors that may be used to deposit the ruthenium-containing film 224 as described above may include metalorganic precursors. In some embodiments, the precursor may include: dimethyl-butadienyl-ruthenium, cyclohexadine-Ru-tricarbonyl (C₆H₈—Ru(CO)₃), butadiene-Ru-tricarbonyl (C₄H₆—Ru(CO)₃), di methyl butadiene-Ru-tricarbonyl ((CH₃)₂—C₄H₄—Ru—CO)₃), or modified dienes with ruthenium tricarbonyl (Ru(CO)₃). Each precursor may have a liquid form and may be provided in a bubbler through which a carrier gas is flowed to carry the precursor into the process chamber. The carrier gas may be any compatible inert gas, such as nitrogen or a noble gas, such as argon, helium, or the like. The carrier gas may be provided at about 100 to about 1000 sccm, or from about 300 to about 700 sccm. The precursor may be delivered to the chamber at a rate from about 1 to about 50 sccm.

During deposition of the ruthenium-containing film 224 at 102, the temperature inside the chamber, or of the substrate, may range from about 150 to about 300 degrees Celsius, or from about 200 to about 250 degrees Celsius. The pressure in the chamber may range from about 3 to about 10 Torr, or from about 1 to about 30 Torr. The deposition process at 102 may be carried out for a first period of time suitable to provide a desired thickness of the ruthenium-containing film 224 prior to proceeding to process the ruthenium-containing film 224 as discussed below to reduce carbon content at 104 or reduce oxygen content at 106. In some embodiments, the ruthenium-containing film 224 may be deposited to a desired thickness ranging from about 5 to about 50 angstroms at 102. Alternatively, as discussed below at 108, the ruthenium-containing film 224 may be deposited to a desired thickness by sequentially repeating the method 100, for example, repeating steps 102 and 104, or repeating steps 102, 104 and 106 until a desired thickness of the ruthenium-containing film 224 is achieved.

At 104, the deposited ruthenium-containing film 224 may be exposed to an hydrogen-containing gas to remove at least some carbon (C) from the deposited ruthenium-containing film 224 as depicted in FIG. 2B. Exposure to the hydrogen-containing gas may advantageously remove carbon from the deposited ruthenium-containing film 224 as well as improve crystallinity of the ruthenium-containing film 224 without substantially degrading surface morphology and/or thickness uniformity of the deposited ruthenium-containing film 224.

The deposited ruthenium-containing film 224 may be exposed to the hydrogen-containing gas in the same CVD chamber as used for depositing the ruthenium-containing film 224, or alternatively, in a different chamber configured for providing the hydrogen-containing gas, such as a chamber configured for annealing, such as a thermal oxidation chamber, rapid thermal process (RTP) chamber, a degas chamber, or the like. The hydrogen-containing gas may be provided in a range of about 500 to about 1000 sccm. The ruthenium-containing film 224 may be exposed to the hydrogen-containing gas for a second period of time. The duration of the second period of time may be dependent upon the thickness of the ruthenium-containing film 224 deposited at 102. In some embodiments, the second period of time may range from about 1 to about 10 minutes, or about 5 minutes, or about less than 2 minutes, such as between about 60 to about 300 seconds.

The ruthenium-containing film 224 may be exposed to the hydrogen-containing gas at the same pressure and temperature as disclosed above at 102 for depositing the ruthenium-containing film 224. For example, in some embodiments, the substrate temperature may range from about 200 to about 400 degrees Celsius, or about 250 degrees Celsius, or about 300 degrees Celsius. In some embodiments, the pressure in the process chamber may be about 2 to about 30 Torr during exposure to the hydrogen-containing gas.

The hydrogen-containing gas may include one or more of hydrogen (H₂), HCOOH, a hydrogen (H) radical, or a hydrogen (H₂) plasma. In some embodiments, the hydrogen-containing gas may be hydrogen (H₂). The removal of carbon from the ruthenium-containing film 224 at 104 may improve resistivity in the layer. For example, in some embodiments, after removing the carbon, the resistivity of the ruthenium-containing film 224 may be reduced to about 60 μOhm-cm or less.

At 106, and optionally, the deposited ruthenium-containing film 224 may be exposed to an oxygen-containing gas to at least one of remove at least some carbon (C) or add oxygen (O) to the deposited ruthenium-containing film 224 as depicted in FIG. 2B. Exposure to the oxygen-containing gas may advantageously remove carbon from the deposited ruthenium-containing film 224 as well as improve crystallinity of the ruthenium-containing film 224 without substantially degrading surface morphology and/or thickness uniformity of the deposited ruthenium-containing film 224. For example, the oxygen-containing gas may interact with carbon in the deposited ruthenium-containing film 224 to form an exhaustible effluent, such as a CₓO_{y}, where x and y are integers. Exemplary exhaustible effluents may include carbon monoxide (CO), carbon dioxide (CO₂), HCOₓ, or water vapor (H₂O).

The deposited ruthenium-containing film 224 may be exposed to the oxygen-containing gas in the same CVD chamber as used for depositing the ruthenium-containing film 224, or alternatively, in a different chamber configured for providing the oxygen-containing gas, such as an oxidation chamber or the like. The oxygen-containing gas may be provided in a range of about 500 to about 1000 sccm. The ruthenium-containing film 224 may be exposed to the oxygen-containing gas for a third period of time. The duration of the third period of time may be dependent upon the thickness of the ruthenium-containing film 224 deposited at 102. In some embodiments, the third period of time may range from about 5 to about 60 seconds. The ruthenium-containing film 224 may be exposed to the oxygen-containing gas at the same pressure and temperature as disclosed above at 102 for depositing the ruthenium-containing film 224. The oxygen-containing gas may include one or more of oxygen (O₂), water vapor (H₂O), or hydrogen peroxide (H₂O₂). In some embodiments, the oxygen-containing gas may be O₂.

The exposure to the oxygen-containing gas at 106 may result in incorporation of oxygen into the deposited ruthenium-containing film 224 in addition to the removal of carbon from the film 224. The oxygen content in the deposited ruthenium-containing film 224 after exposure to the oxygen-containing gas at 106 may range from less than about 1 to about 10 atomic percent, or in some embodiments, about 5 to 10 atomic percent. In some embodiments, the oxygen content may be at least about 8 atomic percent. The removal of carbon from and/or incorporation of oxygen into the deposited ruthenium-containing film 224 may be most effective when the ruthenium-containing film 224 is relatively thin, for example, about 10 to about 50 angstroms.

Further, the oxygen content can be changed depending on the length of exposure time (e.g., the third period of time) to the oxygen-containing gas. For example, if lower resistivity and higher throughput is desired, the third period of time may be between about 5 to about 60 seconds. The oxygen content in the deposited ruthenium-containing film 224 may advantageously contributes to the adhesion of the ruthenium-containing film 224 on a surface of the substrate 200, such as on a surface of the barrier layer 215 disposed in the opening 202. In some embodiments, at completion of 106, the resistively of deposited ruthenium-containing film 224 may range from about 50 to about 70 μOhm-cm or less.

As discussed above, the method 100 may be performed in any of several combinations of the processes discussed above. For example, the film 224 may be deposited to the desired thickness at 102, and then exposed to the hydrogen-containing gas, and then, optionally, exposed to the oxygen-containing gas at 106. Alternatively, at 108, one or more processes at 102, 104, and 106 may be repeated to form the film 224 to the desired thickness. For example, if the desired thickness is substantially thicker than that which is sufficient to effectively remove carbon at 104 and/or optionally at 106, then an iterative deposition process may be most effective. For example, the iterative process at 108 may include repeating 102, 104, and optional 106 in the same order and for the same periods of time to achieve the same carbon content and/or oxygen content at each iteration.

Alternatively, 102, 104, and 106 may be repeated in any suitable order to tailor the film 224 to a desired thickness and/or scaling of carbon content and/or oxygen content. For example, in some applications, it may be more desirable to have higher oxygen content proximate the surface of substrate 200 for improved adhesion to an underlying substrate and less at a terminal surface of the layer 224 for a desired resistivity. Other combinations which tailor properties of the film 224, such as adhesion, resistivity, crystallinity, step coverage, deposition rate or the like between the surface of the substrate 200 and the terminal surface of the film 224 may be utilized. For example, the carbon content and/or oxygen content can be graded in any suitable manner between the surfaces of the film 224 to achieve a desired property.

Thus, the method 100 may provide a ruthenium-containing film 224 comprising ruthenium, carbon, and optionally, oxygen. For example, in some embodiments, the ruthenium-containing film may be predominantly ruthenium oxide (RuO₂) with a small amount of carbon. Further, the ruthenium-containing film may include at least some carbon to the extent that carbon provides desirable layer properties as discussed above. Alternatively, in some embodiments, the ruthenium-containing film 224 may have substantially all carbon removed at 104 and comprise substantially ruthenium and oxygen. In some embodiments, upon completion of method 100, the ruthenium-containing film may have a high deposition rate (e.g., >about 60 angstroms/min), low resistivity (e.g., <about 60 μOhm-cm, or in some embodiments, <about 40 μOhm-cm), good step coverage (e.g., about 95% or greater), and good adhesion on surfaces including at least one of oxides or nitrides.

In some embodiments, a material 226 may be deposited to on the film 224 to fill the opening 202, as illustrated in FIG. 2C. In some embodiments, the material 226 may be a conductive material. The conductive material 224 may be deposited by an electroplating or a similar processing technique. The film 224 may function as a seed layer upon which the conductive material 226 is deposited. The conductive material 226 may include metals, metal alloys, or the like, such as one or more of copper (Cu), aluminum (Al), tungsten (W), or the like. In some embodiments, the conductive material 226 is copper.

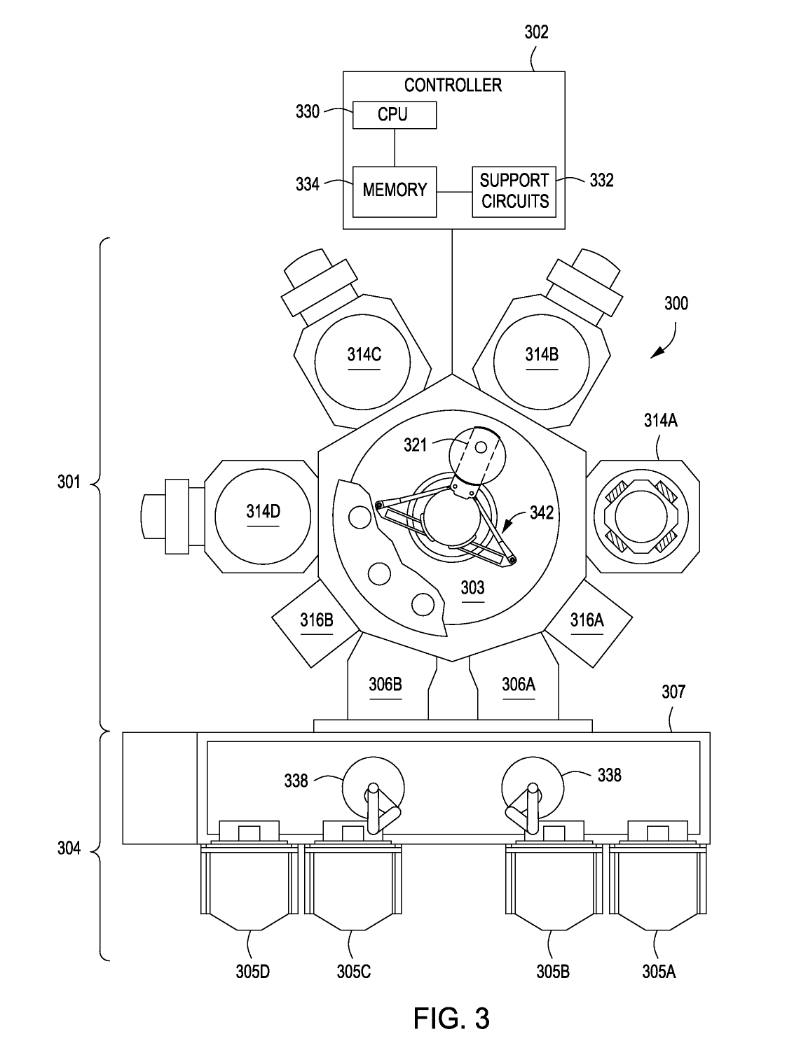

The methods described herein may be performed in individual process chambers that may be provided in a standalone configuration or as part of a cluster tool, for example, an integrated tool 300 (i.e., cluster tool) described below with respect to FIG. 3. Examples of the integrated tool 300 include the CENTURA® and ENDURA® integrated tools, available from Applied Materials, Inc., of Santa Clara, Calif. It is contemplated that the methods described herein may be practiced using other cluster tools having suitable process chambers coupled thereto, or in other suitable process chambers. For example, it may be advantageous in some embodiments, to perform the inventive methods discussed above in an integrated tool such that there are limited or no vacuum breaks between processing steps. For example, reduced vacuum breaks may limit or prevent contamination of the seed layer or other portions of the substrate.

The integrated tool 300 includes a vacuum-tight processing platform 301, a factory interface 304, and a system controller 302. The platform 301 comprises multiple processing chambers, such as 314A, 314B, 314C, and 314D operatively coupled to a vacuum substrate transfer chamber 303. The factory interface 304 is operatively coupled to the transfer chamber 303 by one or more load lock chambers (two load lock chambers, such as 306A and 306B shown in FIG. 3).

In some embodiments, the factory interface 304 comprises at least one docking station 307, at least one factory interface robot 338 to facilitate the transfer of the semiconductor substrates. The docking station 307 is configured to accept one or more front opening unified pod (FOUP). Four FOUPS, such as 305A, 305B, 305C, and 305D are shown in the embodiment of FIG. 3. The factory interface robot 338 is configured to transfer the substrates from the factory interface 304 to the processing platform 301 through the loadlock chambers, such as 306A and 306B. Each of the loadlock chambers 306A and 306B have a first port coupled to the factory interface 304 and a second port coupled to the transfer chamber 303. The load lock chamber 306A and 306B are coupled to a pressure control system (not shown) which pumps down and vents the chambers 306A and 306B to facilitate passing the substrates between the vacuum environment of the transfer chamber 303 and the substantially ambient (e.g., atmospheric) environment of the factory interface 304. The transfer chamber 303 has a vacuum robot 313 disposed therein.

The vacuum robot 313 is capable of transferring substrates 321 between the load lock chamber 306A and 306B and the processing chambers 314A, 314B, 314C, and 314D.

In some embodiments, the processing chambers 314A, 314B, 314C, and 314D, are coupled to the transfer chamber 303. The processing chambers 314A, 314B, 314C, and 314D comprise at least a chemical vapor deposition (CVD) chamber, and optionally, an annealing chamber. Additional chambers may also be provided such as additional a CVD chambers and/or annealing chambers, a physical vapor deposition (PVD) chamber, or the like. CVD and annealing chambers may include any of those suitable to perform all or portions of the methods described herein, as discusses above.

In some embodiments, one or more optional service chambers (shown as 316A and 316B) may be coupled to the transfer chamber 303. The service chambers 316A and 316B may be configured to perform other substrate processes, such as degassing, orientation, substrate metrology, cool down and the like.

The system controller 302 controls the operation of the tool 300 using a direct control of the process chambers 314A, 314B, 314C, and 314D or alternatively, by controlling the computers (or controllers) associated with the process chambers 314A, 314B, 314C, and 314D and the tool 300. In operation, the system controller 302 enables data collection and feedback from the respective chambers and systems to optimize performance of the tool 300. The system controller 302 generally includes a Central Processing Unit (CPU) 330, a memory 334, and a support circuit 332. The CPU 330 may be one of any form of a general purpose computer processor that can be used in an industrial setting. The support circuit 332 is conventionally coupled to the CPU 330 and may comprise a cache, clock circuits, input/output subsystems, power supplies, and the like. Software routines, such as a method as described above may be stored in the memory 334 and, when executed by the CPU 330, transform the CPU 330 into a specific purpose computer (controller) 302. The software routines may also be stored and/or executed by a second controller (not shown) that is located remotely from the tool 300.

Thus, methods for depositing ruthenium-containing films, such as for forming seed layers for interconnect structures have been provided herein. The inventive methods advantageously facilitate improved efficiency, process throughput, and device quality through one or more of reduced seed layer thickness, reduced seed layer resistance, or increased deposition rates. The inventive methods may be utilized with any device nodes, but may be particularly advantageous in device nodes of about 22 nm or less. Further, the inventive methods may be utilized with any type of interconnect structure or material, but may be particularly advantageous with interconnect structures formed by electroplating copper.

While the foregoing is directed to embodiments of the present invention, other and further embodiments of the invention may be devised without departing from the basic scope thereof.

1. A method of depositing a ruthenium-containing film on a substrate, comprising:
(a) depositing a ruthenium-containing film on a substrate using a ruthenium-containing precursor, the deposited ruthenium-containing film having carbon incorporated therein; and
(b) exposing the deposited ruthenium-containing film to a hydrogen-containing gas to remove at least some of the carbon from the deposited ruthenium-containing film.

2. The method of claim 1, further comprising:
(c) repeating (a)-(b) to deposit the ruthenium-containing film to a desired thickness.

3. The method of claim 2, wherein (a) further comprises:
depositing the ruthenium-containing film to a first thickness of about 5 to about 50 angstroms in each iteration.

4. The method of claim 1, wherein the ruthenium-containing precursor includes at least one of dimethyl-butadienyl-ruthenium, cyclohexadine-Ru-tricarbonyl, butadiene-Ru-tricarbonyl, dimethyl butadiene-Ru-tricarbonyl, or modified dienes with ruthenium tricarbonyl.

5. The method of claim 1, wherein the amount of carbon included in the deposited ruthenium-containing film in (a) is at about 2 to about 30 atomic percent.

6. The method of claim 1, wherein the resistivity of the ruthenium-containing film after exposure to the hydrogen-containing gas at (b) is about 60 μOhm-cm or less.

7. The method of claim 1, wherein (b) further comprises:
exposing the deposited ruthenium-containing film to the hydrogen-containing gas for about 1 to about 10 minutes.

8. The method of claim 1, wherein the hydrogen-containing gas includes one or more of hydrogen (H₂), HCOOH, a hydrogen (H) radical, or a hydrogen (H₂) plasma.

9. The method of claim 1, wherein (b) further comprises:
heating the substrate to a temperature of about 200 to about 400 degrees Celsius.

10. The method of claim 1, wherein (a) and (b) each further comprise:
heating the substrate to a temperature of about 200 to about 400 degrees Celsius.

11. The method of claim 1, further comprising:
(c) exposing the ruthenium-containing film in an oxygen-containing gas after (b) to at least one of remove carbon from or add oxygen to the ruthenium-containing film.

12. The method of claim 11, further comprising:
(d) repeating (a)-(c) to deposit the ruthenium-containing film to a desired thickness.

13. The method of claim 11, wherein an amount of oxygen included in the oxygen-containing gas exposed deposited ruthenium-containing film at the conclusion of (c) is at about 1 to about 15 atomic percent.

14. The method of claim 11, wherein the oxygen-containing gas is at least one of oxygen (O₂), water vapor (H₂O), or hydrogen peroxide (H₂O₂).

15. The method of claim 1, wherein depositing the ruthenium-containing film further comprises:
depositing the ruthenium-containing film in an opening formed in a first surface of the substrate, wherein the opening has a sidewall and a bottom surface.

16. The method of claim 15, wherein depositing the ruthenium-containing film further comprises:
depositing the ruthenium-containing film on a barrier layer disposed on the sidewall and bottom surface of the opening.

17. The method of claim 16, wherein the barrier layer comprises at least one of tantalum (Ta) or nitrogen (N).

18. The method of claim 15, wherein the opening has an aspect ratio of height to width of at least 5:1.

19. The method of claim 15, further comprising:
depositing a conductive material on the ruthenium-containing film by an electroplating process to fill the opening.

20. The method of claim 18, wherein the conductive material is copper (Cu).
